(19) United States
(12) Patent Application Publication
(10) Pub. No.: US 2003/0062254 A1
(43) Pub. Date: Apr. 3, 2003

(54) Method and apparatus for depositing a metal layer

(76) Inventors: Seung-Soo Choi, Gyeonggi-do (KR); Seung-Cheol Choi, Gyeonggi-do (KR)

Correspondence Address: VOLENTINE FRANCOS, P.L.L.C., Suite 150, 12200 Sunrise Valley Drive, Reston, VA, 20191, US

(21) Appl. No.: 10/245,285

(22) Filed: Sep. 18, 2002

(30) Foreign Application Priority Data
Sep. 28, 2001 (KR) 2001-0060575

(51) Int. Cl. C23C 14/32

(52) U.S. Cl. 204/192.3; 204/298.25; 204/298.08; 204/192.17

(57) ABSTRACT

A method and an apparatus for depositing a metal layer on a substrate use a sputtering technique wherein first sputter particles sputtered from a first target including a metal are deposited on the substrate. A first metal layer portion having a first thickness corresponding to 40 to 60% of the whole deposition thickness is formed on the substrate. Second sputter particles sputtered from a second target including a metal identical to the first target are deposited on the first metal layer portion. Thus, a second metal layer portion including a material identical to the first metal layer portion and having a second thickness corresponding to 40 to 60% of the whole deposition thickness is formed on the first metal layer portion. When depositing the second metal layer portion, a radio frequency bias is applied to a bottom surface of the substrate so that the first and second sputter particles deposited on the substrate are resputtered towards the surface of the substrate. Accordingly, the metal layer capable of sufficiently filling the metal in a contact hole or a via hole can be achieved.

### CROSS-REFERENCES TO RELATED APPLICATIONS

This application relies for priority upon Korean Patent Application No. 2001-60575, filed on Sep. 28, 2001, the contents of which are herein incorporated by reference in their entirety for all purposes as if fully set forth herein.

### BACKGROUND AND SUMMARY

1. Technical Field

The present invention relates to a method and an apparatus for depositing a metal layer, and more particularly to a method and an apparatus for depositing a metal layer on a substrate by using a sputtering technique.

2. Description of the Related Art

Recently, as information media, such as computers are widely used, the semiconductor industry makes great strides. In a functional aspect, a semiconductor device is required to be operated at a high speed and to have a large storage capacity. To this end, the semiconductor technology is developed to improve the integration degree, the reliability and the response speed of the semiconductor device.

As the semiconductor manufacturing technique is developed, there are strict requirements for a metal wiring process. Particularly, since the recent semiconductor device manufacturing process requires a design rule below 0.15 μm, there are strict requirements for the profile of a contact hole or a via hole having a high aspect ratio. Accordingly, in the metal wiring process, sufficiently filling up the contact hole or via hole with a metal forming a metal wiring is important.

Examples of the metal wiring processes for filling up the contact hole or via hole with the metal are disclosed in U.S. Pat. No. 5,633,201 (issued to Choi), U.S. Pat. No. 5,814,556 (issued to Wee), and U.S. Pat. No. 6,121,134 (issued to Burton).

U.S. Pat. No. 5,633,201 discloses a metal wiring process for filling a contact hole with a metal including tungsten. The metal including tungsten is preferably filled in the contact hole as compared with a metal including aluminum. Tungsten has a specific resistance of 5.5×10E−8 Ω·m at the temperature of about 20° C. while aluminum has a specific resistance of 1.6×10E−8 Ω·m at the temperature of about 20° C. That is, tungsten has a specific resistance higher than aluminum. Accordingly, the metal including tungsten has a contact resistance higher than a contact resistance of the metal including aluminum. Therefore, although the metal including tungsten can be preferably filled in the contact hole, the contact resistance thereof is higher than the contact resistance of the metal including aluminum.

U.S. Pat. No. 5,814,556 discloses a metal wiring process for filling a contact hole with a metal by using a reflow process. The reflow process is carried out above the melting temperature of aluminum. Accordingly, a time for controlling the temperature is required in the reflow process, thereby lowering the productivity. In addition, the temperature control in the reflow process is limited, so the contact hole is incompletely filled with the metal, frequently.

U.S. Pat. No. 6,121,134 discloses an LTS (long throw sputter) technique. According to the LTS technique, a metal is deposited in a sputtering device while maintaining the distance between a substrate and a target by at least 170 mm. Since the distance between the substrate and the target is at least 170 mm, not only is the collision probability between sputter particles lowered, but also the collision probability between the sputter particle and gas is lowered. Since the collision probability is lowered, the straightness of the sputter particles can be ensured. Therefore, the contact hole is easily filled with the metal. When the contact hole has an aspect ratio more than 2.5:1, there are limitations to fill the contact hole with the metal, because it is difficult to ensure infinite straightness of the sputter particles. In addition, the LTS technique requires a long time for moving the sputter particles towards the substrate, thereby lowering the productivity.

In order to solve the above problems, there has been suggested a method for sufficiently complementing a metal through a reflow process after filling the contact hole with the metal by using the LTS technique. However, the above method also has a limitation for filling the metal when the contact hole has an aspect ratio more than 4:1.

Recently, a magnet is used for ensuring the straightness of the sputter particles. An example of a metal wiring process utilizing the magnet is disclosed in U.S. Pat. No. 5,830,327 (issued to Kolenkow).

According to the disclosure in U.S. Pat. No. 5,830,327, the contact hole is sufficiently filled with the metal by utilizing the magnet. However, the magnet is not suitable for realizing a high-density plasma process.

As mentioned above, according to the conventional metal wiring processes, completely filling up the contact hole or via hole with the metal is difficult.

Accordingly, it is required to provide a metal wiring process capable of improving the productivity and the reliability of a semiconductor device.

The present invention has been made to solve the above problems of the prior arts, therefore, it is a first object of the present invention to provide a method for depositing a metal layer to sufficiently fill a contact hole or a via hole with a metal.

A second object of the present invention is to provide an apparatus for depositing a metal layer to sufficiently fill a contact hole or a via hole with a metal.

In one aspect of the present invention, there is provided a method for depositing a metal layer, the method comprising forming on a substrate a first metal layer portion having a first thickness corresponding to 40 to 60% of a whole deposition thickness of the metal layer by depositing on the substrate first sputter particles sputtered from a first target including a first material; and forming a second metal layer portion on the first metal layer portion, the second metal layer portion having a second thickness corresponding to 40 to 60% of the whole deposition thickness of the metal layer, by depositing on the first metal layer portion second sputter particles sputtered from a second target including a second material identical to the first material, wherein the first and second sputter particles deposited on the substrate are re-sputtered towards a first surface of the substrate by applying a radio frequency bias to a second surface of the substrate, that is opposite to the first surface, when depositing the second metal layer portion.

In another aspect of the present invention, there is provided a method for depositing a metal layer, the method comprising depositing on a substrate a first metal layer portion having a first thickness corresponding to 40 to 60% of a whole deposition thickness of the metal layer by depositing on the substrate first sputter particles at a first temperature and pressure; and forming a second metal layer portion on the first metal layer portion, the second metal layer portion having a second thickness corresponding to 40 to 60% of the whole deposition thickness of the metal layer, by depositing on the first metal layer portion second sputter particles sputtered at a second temperature and pressure, wherein the first and second sputter particles deposited on the substrate are re-sputtered towards a first surface of the substrate by increasing a radio frequency bias applied to a second surface of the substrate when depositing the second metal layer portion as compared to a radio frequency bias applied to the second surface of the substrate when depositing the first metal layer portion.

In yet another aspect of the present invention, there is provided an apparatus for depositing a metal layer, the apparatus comprising: a first sputtering chamber for accommodating a first chuck on which a substrate is loaded and a first target that is positioned opposite to the first chuck and includes a first metal, the first sputtering chamber being adapted to form on the substrate a first metal layer portion having a first thickness corresponding to about 40 to 60% of a whole deposition thickness of the metal later by depositing first sputter particles sputtered from the first target; a second sputtering chamber for accommodating a second chuck on which the substrate is loaded and a second target positioned opposite to the second chuck and including a second metal, the second sputtering chamber being adapted to form on the first metal layer a second metal layer portion including a second material and having a second thickness corresponding to about 40 to 60% of the whole deposition thickness of the metal layer by depositing second sputter particles sputtered from the second target on the first metal layer portion; and a bias applying means connected to the second chuck of the second sputtering chamber for resputtering the first and second sputter particles deposited on the substrate into a first surface of the substrate by applying a radio frequency bias to a second surface of the substrate, that is opposite to the first surface, when depositing the second metal layer portion.

According to the above method and apparatus of the present invention, the sputter particles are resputtered due to the radio frequency bias applied to the bottom surface of the substrate when depositing the metal layer. Accordingly, the contact hole or via hole is sufficiently filled with the metal forming the metal layer.

### BRIEF DESCRIPTION OF THE DRAWINGS

The above objects and other advantages of the present invention will become more apparent by describing in detail preferred embodiments thereof with reference to the attached drawings in which:

FIG. 1 is a schematic view showing an apparatus for depositing a metal layer according to one embodiment;

FIG. 2 is a schematic view showing an embodiment of a first sputtering chamber shown in FIG. 1;

FIG. 3 is a schematic view showing an embodiment of a second sputtering chamber shown in FIG. 2;

FIG. 4 is a schematic view showing an electrostatic chuck according to one embodiment;

FIG. 5 is schematic view showing an embodiment of a third sputtering chamber shown in FIG. 2;

FIGS. 6A to 6D are sectional views showing an embodiment of a method for depositing a metal layer; and

FIG. 7 is a sectional view showing a movement of first and second sputter particles deposited in a contact hole when a second aluminum layer is deposited.

### DETAILED DESCRIPTION

Hereinafter, embodiments of the present invention will be described in detail.

A first metal layer is formed on a substrate by depositing first sputter particles on a substrate. The first sputter particles are sputtered from a first target including a metal. The first metal layer has a first thickness corresponding to about 40 to 60% of a whole deposition thickness of the metal layer formed on the substrate. That is, when the whole deposition thickness of the metal layer is 8,000 Å, the first thickness of the first metal layer is about 3,200 to 4,800 Å, preferably, 4,000 Å.

Then, a second metal layer is formed by depositing second sputter particles on the first metal layer. The second sputter particles deposited on the first metal layer are sputtered from a second target including a metal. The second target is preferably comprised of a metal identical to the first target. In that case, the second sputter particles are made of a material identical to the first sputter particles. Thus, the first and second metal layers are made of the same material. The second metal layer is formed such that it has a second thickness corresponding to about 40 to 60% of the whole deposition thickness of the metal layer formed on the substrate. That is, when the whole deposition thickness of the metal layer is about 8,000 Å, the second thickness of the second metal layer is about 3,200 to 4,800 Å, preferably, 4,000 Å.

The second target may be comprised of a metal different from the first target. In this case, a composite layer including first and second metal materials different from each other may be formed.

When the second metal layer is formed, a radio frequency bias is applied to a bottom surface of the substrate. By applying the radio frequency bias, the first and second sputter particles deposited on the substrate are resputtered into a surface of the substrate. Thus, the first and second sputter particles deposited around the contact hole or via hole are sufficiently filled in the contact hole or via hole through the resputtering action.

Hereinafter, the technique for applying the radio frequency bias when depositing the metal layer will be described in further detail.

Methods for depositing a metal layer while applying a radio frequency bias are disclosed in Korean Patent Laid-open Publication No. 1998-41860, Japanese Patent Laid-open Publication No. 8-213322, and U.S. Pat. No. 6,197,167 (issued to Tanaka). These patents disclose a mechanism for inducing an impact to the sputter particles. These patents also disclose a method for forming a metal layer and a method for applying a bias when performing a reflow process after the metal layer has been formed. However, these patents do not disclose the resputtering of the sputter particles. These patents also do not disclose a method for dividing the metal layer into first and second metal layers, which is disclosed in the present invention. particularly, these patents do not teach a method for applying a bias when forming the second metal layer. In addition, according to the above patents, a failure, such as a void, is created in the contact hole or via hole when depositing the metal layer. The result of a metal layer deposited according to the above patents will be described later.

U.S. Pat. No. 5,804,501 (issued to Kim) discloses a method for forming a metal layer including a first metal layer formed through a chemical vapor deposition process and a second metal layer formed through a sputtering process. However, the above patent uses the chemical vapor deposition process. In addition, the above patent does not teach a method for applying a radio frequency bias when forming the second metal layer.

Beneficially, the metal layer includes an aluminum layer or an aluminum alloy layer. Aluminum is frequently used for the metal layer.

Beneficially, the first metal layer is deposited at room temperature. In the LTS technique, the aluminum layer or the aluminum alloy layer can be deposited at room temperature. Thus, the first metal layer is deposited at a temperature of about 15 to 30° C., preferably at a temperature of about 20° C. In addition, beneficially the first metal layer is deposited at a pressure of about 0.2 to 0.4 mTorr, preferably about 0.3 mTorr. In the LTS technique, the aluminum layer or the aluminum alloy layer can be deposited under the above pressure condition.

The second metal layer is deposited at a temperature of about 420 to 660° C. when depositing the metal layer. If the second metal layer includes the aluminum layer or the aluminum alloy layer, the reflow effect can be obtained from the above temperature condition when depositing the second metal layer. If the deposition process is carried out at the temperature below 420° C., the reflow effect is rarely obtained. The temperature of 660° C. is a melting point of aluminum. Thus, if the temperature exceeds 660° C. when depositing the metal layer, the aluminum will melt so that the reflow is overwhelming.

If a radio frequency bias less than about 150 Watts is applied to the bottom surface of the substrate when depositing the second metal layer, the effect of the radio frequency bias is not sufficient. In addition, if a radio frequency bias greater than about 650 Watts is applied to the bottom surface of the substrate, it is difficult to control the radio frequency bias. Accordingly, a radio frequency bias of about 150 to 650 Watts, preferably about 570 Watts, is applied to the bottom surface of the substrate.

The metal layer can be formed on a barrier metal layer. In detail, the metal layer including the first and second metal layers is formed after forming the barrier metal layer on the substrate. The barrier metal layer is deposited on the substrate through a sputtering process. Thus, the barrier metal layer is deposited on the substrate by depositing third sputter particles, which are sputtered from a third target including a barrier metal, on the substrate. Beneficially, the barrier metal includes titanium or titanium nitride. In that case, the barrier metal layer includes a titanium layer or a titanium nitride layer.

The metal layer can be subject to a reflow process. In detail, after forming the metal layer including the first and second metal layers on the substrate, the metal layer is subject to the reflow process. Accordingly, the contact hole or via hole can be sufficiently filled with the metal forming the metal layer. When the metal layer includes aluminum, the reflow process is carried at a temperature above the melting point of aluminum. Thus, the reflow process is carried out at the temperature above 660° C.

As mentioned above, the metal layer including the first and second metal layers is formed on the barrier metal layer after forming the barrier metal layer on the substrate, and the metal layer is subject to the reflow process. In addition, the radio frequency bias is applied to the bottom surface of the substrate when forming the second metal layer. Thus, the metal layer capable of sufficiently filling the metal into the contact hole and via hole can be achieved. Particularly, since the metal layer is formed at room temperature, it is possible to restrain the growing of grains of the metal forming the first metal layer. Therefore, the metal without grains grown thereon is easily resputtered into the surface of the substrate when forming the second metal layer. Accordingly, it is possible to obtain the metal layer with the contact hole or via hole being sufficiently filled with the metal.

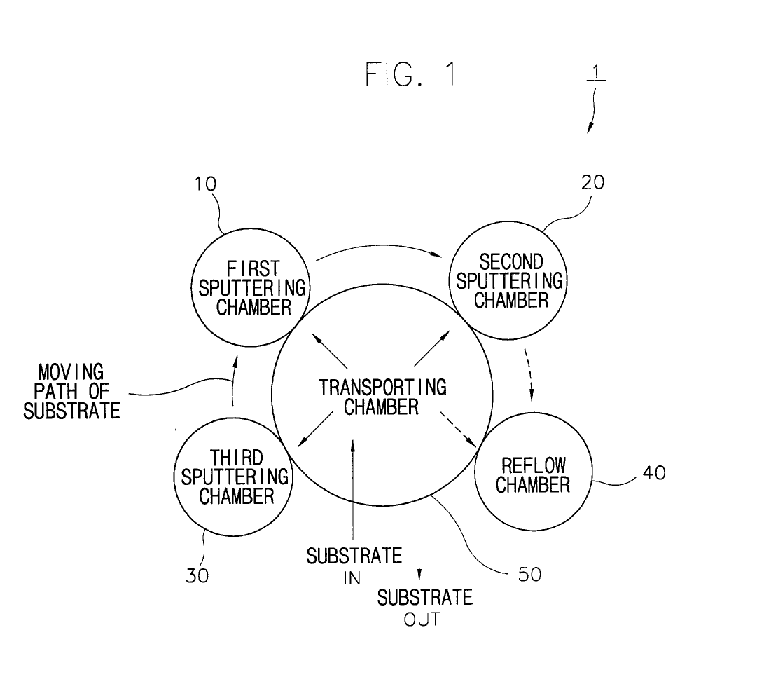

FIG. 1 shows an apparatus 1 for depositing the metal layer on the substrate. Referring to FIG. 1, the apparatus 1 includes a first sputtering chamber 10 for forming the first metal layer.

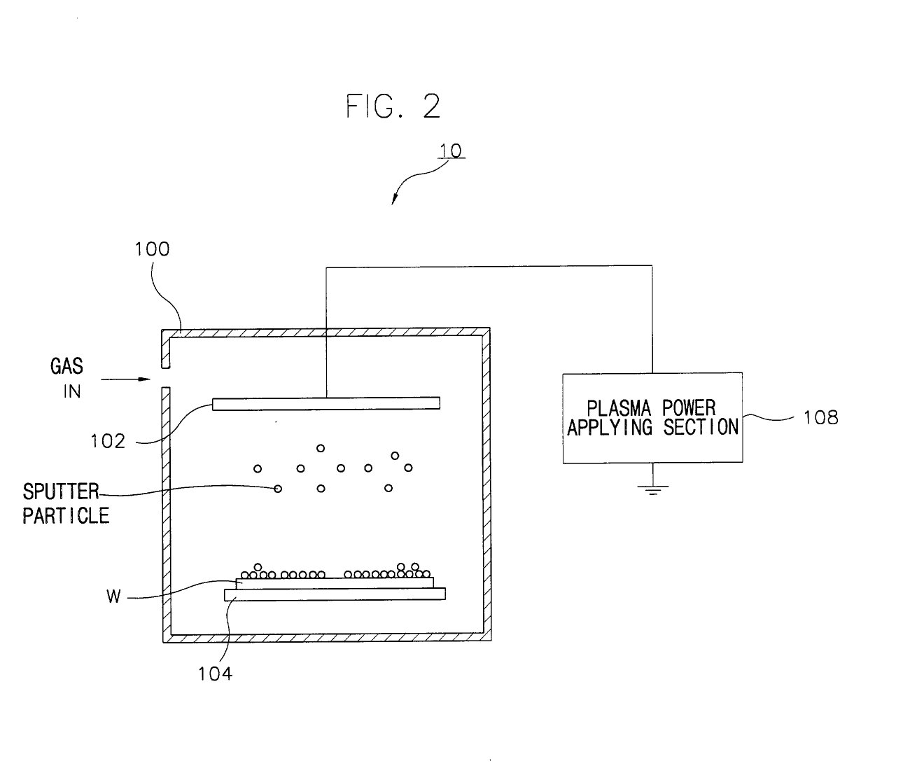

FIG. 2 shows an embodiment of the first sputtering chamber 10. Referring to FIG. 2, the first sputtering chamber 10 includes a first chuck 104 for loading the substrate W thereon and a first target 102 positioned in opposition to the first chuck 104. The first chuck 104 is positioned at a lower portion of the first sputtering chamber 10 and the first target 102 is positioned at an upper portion of the first sputtering chamber 10. The first chuck 104 includes an electrostatic chuck (ESC). The first metal layer is formed at a room temperature. By using the electrostatic chuck, the cooling effect of the room temperature can be achieved. The first target 102 comprises a metal. That is, the first target 102 comprises the metal forming the first metal layer. Thus, the sputter particles sputtered from the first target 102 are deposited on the substrate, thereby forming the first metal layer. In detail, the first target 102 consists of the metal including aluminum or aluminum alloy. Accordingly, the first metal layer deposited on the substrate W may be an aluminum layer or an aluminum alloy layer. In addition, the first metal layer is formed in the first sputtering chamber 10 such that it has a first thickness corresponding to about 40 to 60% of a whole deposition thickness of the metal layer to be formed on the substrate W. That is, when the whole deposition thickness of the metal layer is about 8,000 Å, the first metal layer is adjusted to have the first thickness about 3,200 to 4,800 Å. A gas line (not shown) for introducing gas is connected to one side of the first sputtering chamber 10. In addition, a plasma power applying section 108 is connected to the first sputtering chamber 10. The plasma power applying section 108 is connected to the first target 102. Accordingly, it is possible to form the first metal layer under the plasma state.

The apparatus 1 includes a second sputtering chamber 20 for forming the second metal layer.

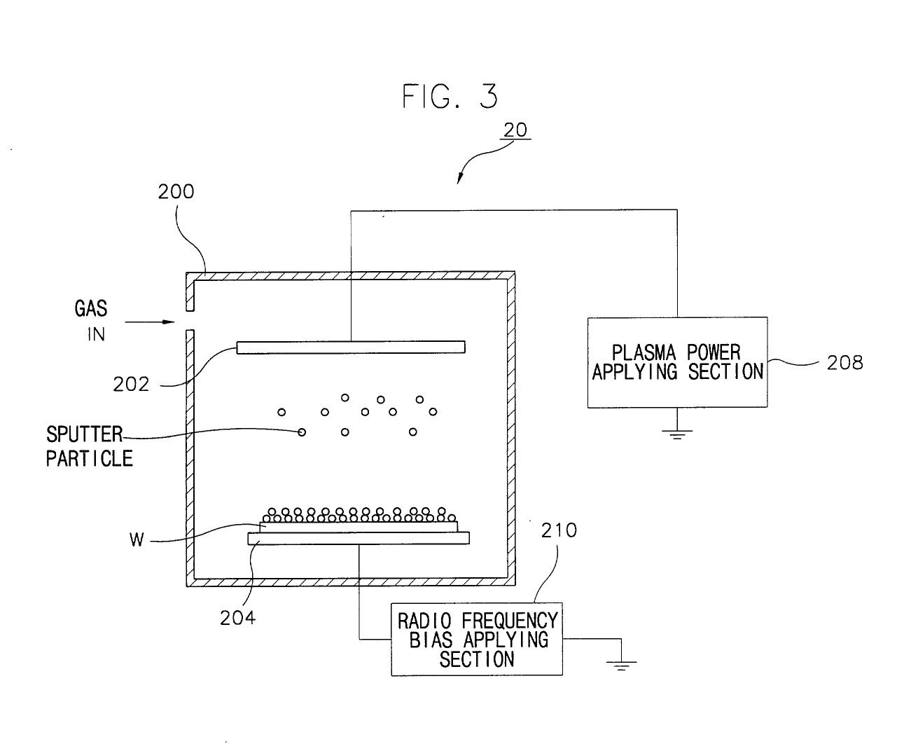

FIG. 3 shows an embodiment of the second sputtering chamber 20. Referring to FIG. 3, the second sputtering chamber 20 includes a second chuck 204 for loading the substrate W thereon and a second target 202 positioned in opposition to the second chuck 204. The second chuck 204 is positioned at a lower portion of the second sputtering chamber 20 and the second target 202 is positioned at an upper portion of the second sputtering chamber 20. The second chuck 204 includes a heating chuck for heating the substrate W. The second metal layer is formed at a temperature of about 420 to 660° C. Accordingly, the heating chuck heats the substrate W at a temperature of about 420 to 660° C.

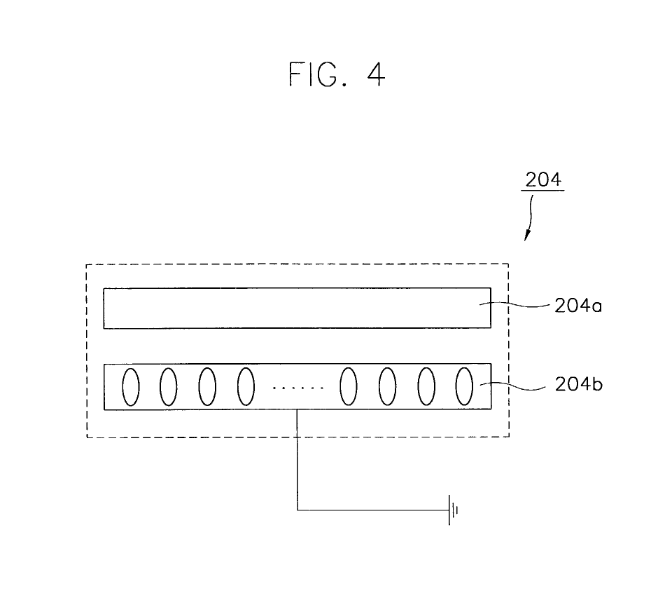

FIG. 4 shows an embodiment of the second chuck 204. Referring to FIG. 4, the second chuck 204 includes an electrostatic chuck 204a and a heating member 204b for heating the substrate W loaded on the electrostatic chuck 204a in the temperature of 420 to 660° C. The heating member 204b includes a halogen lamp, a heating coil, and the likes.

The second target 202 comprises a metal. In detail, the second target 202 may comprise the same metal as in the first target 102. Thus, the second metal layer is formed by depositing sputter particles sputtered from the second target 202 on the first metal layer formed in the substrate W. In detail, the second target 202 may comprise the metal including aluminum or aluminum alloy. In that case, the second metal layer deposited on the first metal layer of the substrate W is an aluminum layer or an aluminum alloy layer. In addition, the second metal layer is formed in the second sputtering chamber 20 such that it has a second thickness corresponding to about 40 to 60% of the whole deposition thickness of the metal layer to be formed on the substrate W. That is, when the whole deposition thickness of the metal layer is 8,000 Å, the second metal layer is adjusted to have the second thickness about 3,200 to 4,800 Å. A gas line (not shown) for introducing gas is connected to one side of the second sputtering chamber 20. In addition, a plasma power applying section 208 is connected to the second sputtering chamber 20. The plasma power applying section 208 is connected to the second target 202. Accordingly, it is possible to form the second metal layer under the plasma state.

In addition, a radio frequency bias applying section 210 is connected to the second sputtering chamber 20. The second chuck 204 is connected to the radio frequency bias applying section 210. Thus, the radio frequency bias is applied to the bottom surface of the substrate W while depositing the second metal layer. By applying the radio frequency bias, the first and second sputter particles deposited on the substrate W are resputtered to the surface of the substrate W. Accordingly, the contact hole or via hole formed in the substrate W is easily filled with the first and second sputter particles. At this time, if a radio frequency bias less than about 150 Watts is applied to the bottom surface of the substrate W, the effect of the radio frequency bias is not sufficient. In addition, if a radio frequency bias greater than about 650 Watts is applied to the bottom surface of the substrate W, it is difficult to control the radio frequency bias. Accordingly, a radio frequency bias of about 150 to 650 Watts is applied to the bottom surface of the substrate W. In addition, the radio frequency bias applying section 210 includes a matching unit (not shown) for properly controlling the radio frequency bias. The matching unit provides an induced electromotive force for adjusting the impedance component.

Therefore, the second metal layer is formed by using the second sputtering chamber 20 after depositing the first meal layer on the substrate W by using the first sputtering chamber. At this time, the first sputtering chamber 10 performs the process at room temperature. Accordingly, growth of the grains of the particles of the first metal layer deposited on the substrate W may be prevented. In addition, the second sputtering chamber 20 performs the process under the high temperature with applying the radio frequency bias. Thus, the reflow effect can be achieved from the high temperature and the resputtering effect can be obtained through the radio frequency bias. At this time, since the growth of the particles of the first metal layer is prevented, the resputtering effect is maximized.

The apparatus 1 further includes a third sputtering chamber, a reflow chamber and a transporting chamber.

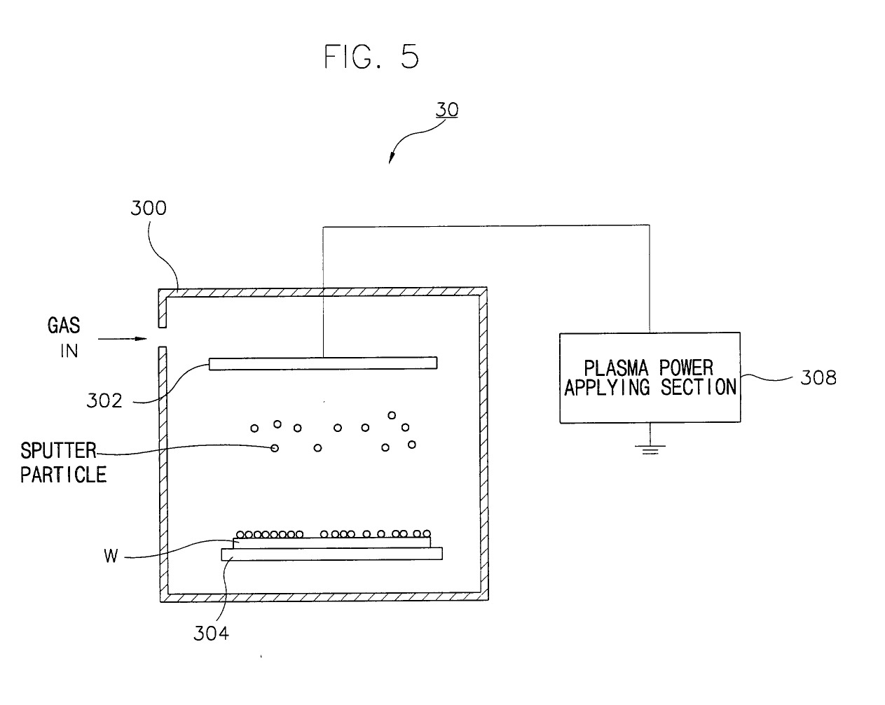

FIG. 5 shows an embodiment of a third sputtering chamber 30. Referring to FIG. 5, the third sputtering chamber 30 includes a third chuck 304 for loading the substrate W thereon and a third target 302 positioned in opposition to the third chuck 304. The third chuck 304 is positioned at a lower portion of the third sputtering chamber 30 and the third target 302 is positioned at an upper portion of the third sputtering chamber 30. The third chuck 304 includes an electrostatic chuck (ESC) and the third target 302 comprises a metal. That is, the third target 302 comprises a metal forming the third metal layer. Thus, the sputter particles sputtered from the third target 302 are deposited on the substrate W, thereby forming the third metal layer. In detail, the third target 302 may comprise a metal including titanium or titanium nitride. In that case, the third metal layer formed on the substrate W is a titanium layer or a titanium nitride layer. The third metal layer is a barrier metal layer. In addition, if the first and second metal layers are an aluminum layer or an aluminum alloy layer, beneficially, the barrier metal layer is a titanium layer or a titanium nitride layer. Thus, the barrier metal layer restrains the material-movement (that is referred to as an aluminum spiking) between the aluminum particles forming the aluminum layer and particles forming the substrate W. In addition, a plasma power applying section 308 is connected to the third sputtering chamber 30. The plasma power applying section 308 is connected to the third target 302. Accordingly, it is possible to form the third metal layer under the plasma state.

The reflow chamber 40 heats the substrate W at a high temperature above a melting point of aluminum after the metal layer has been formed. It is also possible to omit the process utilizing the reflow chamber 40 because the reflow process can be carried out in the second sputtering chamber 20. If the reflow process is carried out by using the reflow chamber 40, the contact hole or via hole is more sufficiently filled with the metal.

In addition, the transporting chamber 50 transports the substrate W in the apparatus 1. The transporting chamber 50 has a transporting member (not shown). The transporting member suctions the bottom of the substrate W by using a vacuum. The transporting chamber 50 receives the substrate W from a loadlock chamber (not shown) and sequentially transports the substrate W into the third sputtering chamber 30, the first sputtering chamber 10, the second sputtering chamber 20 and the reflow chamber 40, because the barrier metal layer, the first metal layer and the second metal layer forming processes and the reflow process are sequentially carried out using the apparatus 1.

In addition, the apparatus 1 further includes a degassing chamber (not shown) and a radio frequency etching chamber (not shown). The substrate W transported from a former stage is cleaned in the degassing chamber and a native oxide layer formed on the substrate W is etched in the radio frequency etching chamber before the third metal layer is formed.

Hereinafter, an embodiment of a method of depositing a metal layer will be described in detail with reference to the accompanying drawings.

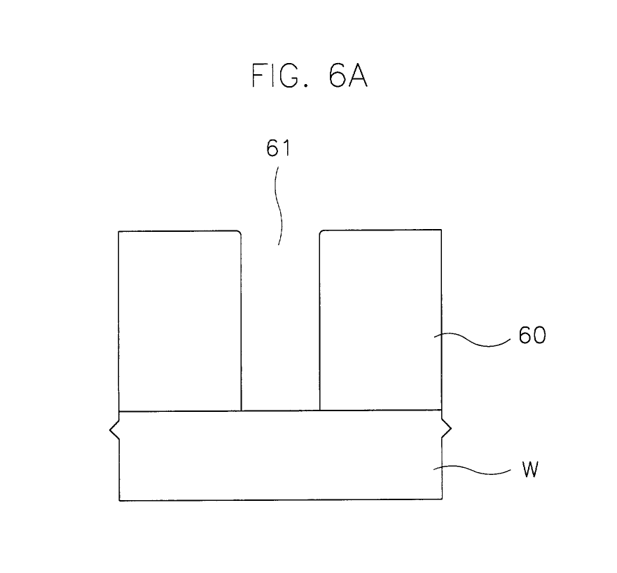

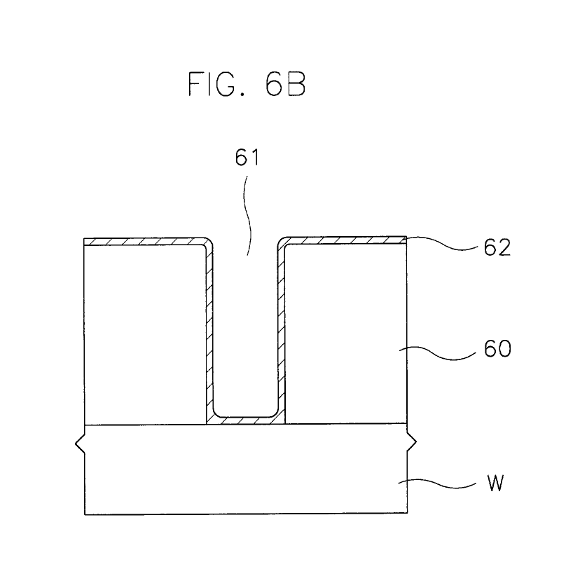

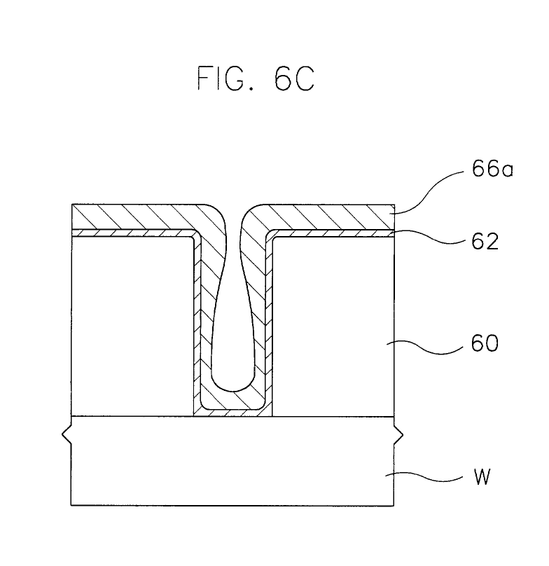

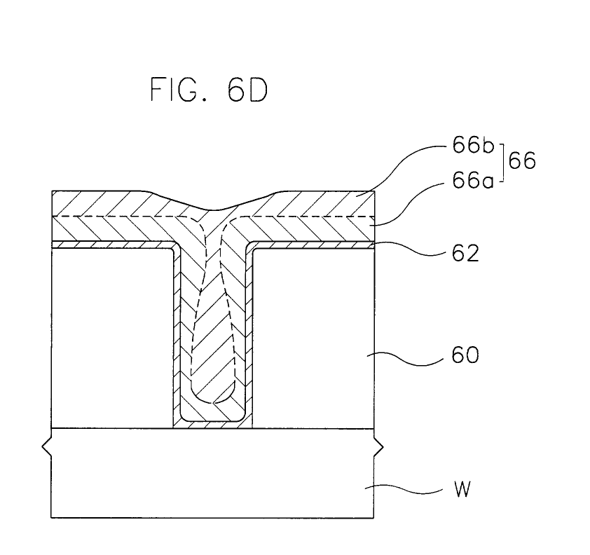

FIG. 6A shows the substrate W on which an insulating interlayer 60 having a contact hole 61 is formed. The insulating interlayer 60 includes insulating material, such as BPSG (borophosphosilicate glass), and is formed through a chemical vapor deposition process. The insulating interlayer 60 has a thickness about 14,000 Å. The contact hole 61 has an aspect ratio of 4.5:1, so a contact hole area has a critical dimension (CD) about 0.31 μm.

FIG. 6B shows a barrier metal layer 62 (e.g., a titanium layer) formed on the insulating interlayer 60 having the contact hole 61. The titanium layer 62 is formed as follows.

Firstly, after forming the insulating interlayer 60 having the contact hole 61, the substrate W is transported into the apparatus 1 for depositing the metal layer. At this time, the substrate W is transported from the loadlock chamber into the transporting chamber 50 of the apparatus 1.

Then, the transporting chamber 50 transports the substrate W into the degassing chamber. The substrate W is cleaned in the degassing chamber so as to remove impurities from the substrate W, which are generated when forming the insulating interlayer 60 having the contact hole 61.

Thereafter, the transporting chamber 50 transports the substrate W from the degassing chamber into the radio frequency etching chamber. The native oxide layer formed on the substrate W is etched in the radio frequency etching chamber. The native oxide layer is grown on the substrate W, because the substrate W is exposed to an atmosphere when the substrate W is transported into the loadlock chamber after the insulating interlayer 60 has been formed on the substrate W. Due to the native oxide layer, the electric resistance of the metal wiring increases and failure occurs when depositing the metal layer. For this reason, the native oxide layer is preferably etched by using the radio frequency etching chamber.

In addition, the transporting chamber 50 transports the substrate W from the radio frequency etching chamber into the third sputtering chamber 30. In the third sputtering chamber 30, the titanium layer 62 is sequentially deposited on a lower portion and a sidewall of the contact hole 61 and the insulation interlayer 60. That is, the sputter particles sputtered from the third target 302 comprising of titanium are sequentially deposited on the lower portion and the sidewall of the contact hole 61 and the insulation interlayer 60, thereby forming the titanium layer 62. At this time, the titanium layer 62 has a thickness about 600 Å.

FIG. 6C shows a first metal layer 66a (e.g., first aluminum layer) formed on the titanium layer 62. The first aluminum layer 66a is formed as follows.

The transporting chamber 50 transports the substrate W from the third sputtering chamber 30 into the first sputtering chamber 10. The first aluminum layer 66a is formed on the titanium layer 62 in the first sputtering chamber 10. In detail, the first sputtering chamber 10 is controlled to have a process atmosphere at a temperature of 20° C. and the pressure of 0.3 mTorr. In addition, the plasma power is applied to the first sputtering chamber 10, and argon (Ar) gas is introduced into the first sputtering chamber 10. The process for forming the first aluminum layer 66a is carried out for 60 seconds. Thus, the sputter particles sputtered from the first target 102 comprised of aluminum are deposited on the titanium layer 62, thereby forming the first aluminum layer 66a. The first aluminum layer 66a has a thickness about 4000 Å, which corresponds to half of the whole thickness of the aluminum layer 66. In addition, the first aluminum layer 66a formed at the contact hole area is sunk into the lower portion of the contact hole 61.

FIG. 6D shows a second metal layer 66b (e.g., a second aluminum layer) formed on the first aluminum layer 66a. Thus, the FIG. 6D shows the aluminum layer 66 including the first aluminum layer 66a and the second aluminum layer 66b formed on the substrate W.

The second aluminum layer 66b is formed as follows.

The transporting chamber 50 transports the substrate W from the first sputtering chamber 10 into the second sputtering chamber 20. The second aluminum layer 66b is formed on the first aluminum layer 66a in the second sputtering chamber 20. In detail, the second sputtering chamber 20 is controlled to have a process atmosphere at a temperature of 500° C. and the pressure of 0.3 mTorr. In addition, the plasma power is applied to the second sputtering chamber 20, and argon gas of 10 sccm is introduced into the second sputtering chamber 20. The radio frequency bias is applied to the heating chuck 204 on which the substrate W is loaded. The process for forming the second aluminum layer 66b is carried out for 60 seconds. Thus, the sputter particles sputtered from the second target 202 made of aluminum are deposited on the first aluminum layer 66a, thereby forming the second aluminum layer 66b. The second aluminum layer 66b has a thickness about 4000 Å, which corresponds to half of the whole thickness of the aluminum layer 66. In addition, the second aluminum layer 66b formed in the contact hole area is sufficiently filled into the contact hole 61.

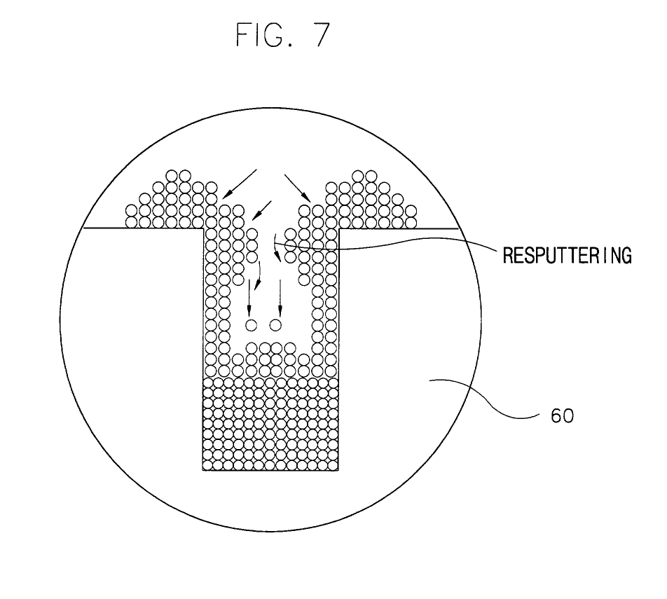

FIG. 7 shows the movement of the first and second sputtered particles deposited on the contact hole area when depositing the second aluminum layer.

Referring to FIG. 7, when depositing the second aluminum layer, the first and second sputtered particles formed in the contact hole area are continuously resputtered towards the lower portion of the contact hole. The reason is that the radio frequency bias is applied to the bottom surface of the substrate when depositing the aluminum layer. That is, by applying the radio frequency bias to the bottom of the substrate, the sputter particles being deposited into an inlet portion of the contact hole collide with the first and second sputter particles deposited on the inlet portion of the contact hole, so the first and second particles are continuously resputtered towards the lower portion of the contact hole. In addition, the first and second sputtered particles deposited in the inlet portion of the contact hole are shifted to the lower portion of the contact hole by the radio frequency bias. The second aluminum layer is formed at the high temperature, so the reflow effect is additionally achieved. Accordingly, the resputtering of the sputter particles is more easily carried out.

Then, the transporting chamber moves the substrate formed with the metal (e.g., aluminum) layer from the second sputtering chamber to the reflow chamber. The reflow process for the aluminum layer is carried out in the reflow chamber. Thus, the contact hole is sufficiently filled with the aluminum layer.

In addition, the transporting chamber transports the substrate from the reflow chamber into the loadlock chamber so as to complete the aluminum layer. Then, the substrate formed with the aluminum layer is transported from the loadlock chamber to an apparatus performing the next process.

As mentioned above, the aluminum layer is formed by sequentially forming the first and second aluminum layers. In addition, the first and second aluminum layers are formed through the sputtering process. The first aluminum layer is formed at room temperature, so that growth of the grains forming the first aluminum layer is prevented. Thus, the resputtering efficiency is improved. When the second aluminum layer is formed, a radio frequency bias is applied to the bottom surface of the substrate. Accordingly, the contact hole or the via hole is sufficiently filled with the aluminum layer. Therefore, the failure generated in the metal wiring process, such as voids, can be prevented.

Hereinafter, the working examples of the present invention will be described in detail.

### EXAMPLE 1

A sputtering apparatus having first and second sputtering chambers was prepared. The first and second sputtering chambers have an LP type magnet and a distance between the substrate and the target was about 193 mm. In addition, first and second target consisting of aluminum were prepared. A sample including an insulating interlayer having a thickness of 9,300 Å, and a titanium layer having a thickness of 1,000 Å was prepared on the substrate for forming the aluminum layer. The insulating interlayer was an oxide material layer. In addition, the insulating interlayer was formed with a contact hole having a critical dimension of 625 nm and an aspect ratio of 0.92:1.

Firstly, the first aluminum layer having a thickness of 4,000 Å was formed on the titanium layer of the sample. Then, the second aluminum layer having a thickness of 4,000 Å was formed on the first aluminum layer with applying the radio frequency bias about 570 Watts.

The sample formed with the aluminum layer was inspected through a scanning electron microscope (SEM). As a result, it was found that the contact hole was sufficiently filled with aluminum. Accordingly, it could be noted that the superior aluminum layer can be obtained by sequentially forming the first and second aluminum layers with applying the radio frequency bias.

### EXAMPLE 2

The aluminum layer in this example was formed in the same manner as in Example 1, except that the thickness of the first aluminum layer was about 2,000 Å, and the second aluminum layer was formed through three steps to have a thickness of 6,000 Å.

The sample formed with the aluminum layer was inspected through a scanning electron microscope (SEM). As a result, it was found that the contact hole was sufficiently filled with aluminum. Accordingly, it could be noted that the superior aluminum layer can be obtained by sequentially forming the first and second aluminum layers while applying the radio frequency bias.

### EXAMPLE 3

The aluminum layer in this example was formed in the same manner as in Example 1, except that the thickness of the first aluminum layer was about 5,000 Å, the second aluminum layer had a thickness about 3,000 Å, and the reflow process was carried out for 90 seconds after forming the aluminum layer including the first and second aluminum layers.

The sample formed with the aluminum layer was inspected through a scanning electron microscope (SEM). As a result, it was found that the contact hole was sufficiently filled with aluminum. Accordingly, it could be noted that the superior aluminum layer can be obtained by sequentially forming the first and second aluminum layers while applying the radio frequency bias.

### Comparative Example 1

The aluminum layer was formed in the same manner as in Example 1, except that the aluminum layer having the thickness about 8,000 Å was formed through a single process. That is, the aluminum layer was formed on a sample identical to the sample used in Example 1 through the single process. In addition, the radio frequency bias about 570 Watts was applied to the bottom surface of the sample when forming the aluminum layer. At that time, the deposition rate of the aluminum layer was about 37 Å/sec.

The sample formed with the aluminum layer was inspected through a scanning electron microscope (SEM). As a result, voids were found in the contact hole.

### Comparative Example 2

The aluminum layer was formed in the same manner as in Comparative Example 1, except that the radio frequency bias about 300 Watts was applied to the bottom surface of the sample. At this time, the deposition rate of the aluminum layer was about 50 Å/sec.

The sample formed with the aluminum layer was inspected through a scanning electron microscope (SEM). As a result, voids were found in the contact hole.

### Comparative Example 3

The aluminum layer was formed in the same manner as in Comparative Example, except that the radio frequency bias is not applied to the bottom surface of the sample. At this time, the deposition rate of the aluminum layer is about 55 Å/sec.

The sample formed with the aluminum layer was inspected through a scanning electron microscope (SEM). As a result, it was found that an inlet area of the contact hole was opened.

As can be noted from Comparative Examples 1 to 3, if the aluminum layer is formed through the single process while applying the radio frequency bias, it is impossible to restrain the growing of grains when a core of aluminum is initially formed. That is, the radio frequency bias promotes the growing of grains. Thus, the grains have a large size. The grains having the large size exert a bad influence on an aluminum flow for forming the aluminum layer. That is, the inlet of the contact hole is closed before the contact hole is filled with aluminum, so voids are frequently created.

As can be noted from Examples 1 to 3 of the present invention, if the aluminum layer is formed through two-step deposition processes while applying the radio frequency bias, it is possible to restrain the growth of grains when a core of aluminum is initially formed, because the radio frequency bias is not applied to the bottom of the substrate in the initial stage. Accordingly, the grains have a small size. Since the grains have a small size, the resputtering is easily generated when performing a next process. Therefore, the contact hole is sufficiently filled with aluminum.

According to the present invention, it is possible to form the metal layer capable of sufficiently filling the contact hole or via hole with the metal. Thus, the reliability of the metal wiring including the metal layer can be improved.

In addition, the failure caused by the contact resistance can be reduced through forming the aluminum metal layer. In addition, though two-step metal deposition processes are carried out, since the first and second aluminum layers are formed with the same material and the same technique, the productivity thereof can be improved.

While the present invention has been described in detail with reference to the preferred embodiments thereof, it should be understood to those skilled in the art that various changes, substitutions and alterations can be made hereto without departing from the scope of the invention as defined by the appended claims.

What is claimed is:

1. A method for depositing a metal layer, the method comprising:
a) forming on a substrate a first metal layer portion having a first thickness corresponding to 40 to 60% of a whole deposition thickness of the metal layer by depositing on the substrate first sputter particles sputtered from a first target including a first material; and
b) forming a second metal layer portion on the first metal layer portion, the second metal layer portion having a second thickness corresponding to 40 to 60% of the whole deposition thickness of the metal layer, by depositing on the first metal layer portion second sputter particles sputtered from a second target including a second material identical to the first material,
wherein the first and second sputter particles deposited on the substrate are resputtered towards a first surface of the substrate by applying a radio frequency bias to a second surface of the substrate, that is opposite to the first surface, when depositing the second metal layer portion.

2. The method as claimed in claim 1, wherein the metal layer includes an aluminum layer or an aluminum alloy layer.

3. The method as claimed in claim 2, wherein the first metal layer portion is formed at a room temperature under a pressure of about 0.2 to 0.4 mTorr.

4. The method as claimed in claim 2, wherein the second metal layer portion is formed at a temperature above about 420° C. and below a melting point of aluminum under a pressure of about 0.2 to 0.4 mTorr and a plasma atmosphere of Ar gas.

5. The method as claimed in claim 1, wherein the radio frequency bias of about 150 to 650 Watts is applied to the second surface of the substrate when depositing the second metal layer portion.

6. The method as claimed in claim 1, further comprising the step of forming a barrier metal layer on the substrate by depositing on the substrate third sputter particles sputtered from a third target including a barrier metal, wherein the first and second metal layer portions are sequentially formed on the barrier metal layer after forming the barrier metal layer on the substrate.

7. The method as claimed in claim 6, wherein the barrier metal layer includes a titanium layer or a titanium nitride layer.

8. The method as claimed in claim 1, further comprising the step of reflowing the metal layer at a high temperature above a melting point of aluminum after forming the first and second metal layer portions.

9. The method as claimed in claim 1, wherein the substrate includes an insulating layer having a contact hole or a via hole formed through a patterning process, and the contact hole or the via hole is filled with the first and second sputter particles through the resputtering.

10. An apparatus for depositing a metal layer, the apparatus comprising:
a first sputtering chamber for accommodating a first chuck on which a substrate is loaded and a first target that is positioned opposite to the first chuck and includes a first metal, the first sputtering chamber being adapted to form on the substrate a first metal layer portion having a first thickness corresponding to about 40 to 60% of a whole deposition thickness of the metal later by depositing first sputter particles sputtered from the first target;
a second sputtering chamber for accommodating a second chuck on which the substrate is loaded and a second target positioned opposite to the second chuck and including a second metal, the second sputtering chamber being adapted to form on the first metal layer a second metal layer portion including a second material and having a second thickness corresponding to about 40 to 60% of the whole deposition thickness of the metal layer by depositing second sputter particles sputtered from the second target on the first metal layer portion; and
a bias applying means connected to the second chuck of the second sputtering chamber for resputtering the first and second sputter particles deposited on the substrate into a first surface of the substrate by applying a radio frequency bias to a second surface of the substrate, that is opposite to the first surface, when depositing the second metal layer portion.

11. The apparatus as claimed in claim 10, wherein the first chuck comprises an electrostatic chuck.

12. The apparatus as claimed in claim 10, wherein the first metal forming the first target includes aluminum.

13. The apparatus as claimed in claim 10, wherein the second chuck comprises a heating chuck that heats the substrate at a temperature above about 420° C. and below a melting point of aluminum.

14. The apparatus as claimed in claim 10, wherein the second chuck is a heating chuck assembly including an electrostatic chuck and a heating member for providing the substrate with a heat source having a temperature above about 420° C. and below a melting point of aluminum.

15. The apparatus as claimed in claim 10, wherein the bias applying means applies the radio frequency bias of about 150 to 650 Watts to the second surface of the substrate.

16. The apparatus as claimed in claim 10, further comprising a third sputtering chamber for accommodating a third chuck on which the substrate is loaded and a third target positioned opposite to the third chuck and including a barrier metal, and for forming a barrier metal layer on the substrate by depositing third sputter particles sputtered from the third target on the substrate, wherein the substrate is transported from the third sputtering chamber to the first sputtering chamber so as to deposit the first metal layer portion on the barrier metal layer.

17. The apparatus as claimed in claim 16, wherein the barrier metal forming the third target includes titanium.

18. The apparatus as claimed in claim 10, further comprising a transporting chamber for transporting the substrate, the transporting chamber sequentially transporting the substrate into the third sputtering chamber, the first sputtering chamber, and the second sputtering chamber.

19. A method for depositing a metal layer, the method comprising:
depositing on a substrate a first metal layer portion having a first thickness corresponding to 40 to 60% of a whole deposition thickness of the metal layer by depositing on the substrate first sputter particles at a first temperature and pressure; and
forming a second metal layer portion on the first metal layer portion, the second metal layer portion having a second thickness corresponding to 40 to 60% of the whole deposition thickness of the metal layer, by depositing on the first metal layer portion second sputter particles sputtered at a second temperature and pressure,
wherein the first and second sputter particles deposited on the substrate are resputtered towards a first surface of the substrate by increasing a radio frequency bias applied to a second surface of the substrate when depositing the second metal layer portion as compared to a radio frequency bias applied to the second surface of the substrate when depositing the first metal layer portion.

20. The method as claimed in claim 10, wherein the radio frequency bias is increased from approximately zero watts when depositing the first metal layer portion to about 150 to 650 Watts when depositing the second metal layer portion.

21. The method as claimed in claim 19, wherein the first temperature is room temperature and the first pressure is about 0.2 to 0.4 mTorr.

22. The method as claimed in claim 21, wherein the second temperature is above about 420° C. and below a melting point of aluminum and the second pressure is about 0.2 to 0.4 mTorr.
